(19) United States
(12) Patent Application Publication
(10) Pub. No.: US 2025/0224292 A1
(43) Pub. Date: Jul. 10, 2025

(54) DETECTION APPARATUS, TRAINING METHOD AND APPARATUS, AND COMPUTER-READABLE STORAGE MEDIUM

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Jie SUN, Beijing (CN); Yue LI, Beijing (CN); Qiuxu WEI, Beijing (CN); Lihui WANG, Beijing (CN); Weilong GUO, Beijing (CN); Taonan ZHANG, Beijing (CN); Nana HE, Beijing (CN); Wenbo CHANG, Beijing (CN); Feng QU, Beijing (CN)

(21) Appl. No.: 18/689,856

(22) PCT Filed: Aug. 25, 2023
(86) PCT No.: PCT/CN2023/114858

§ 371 Date: Mar. 6, 2024

(51) Int. Cl. G01L 9/06; B81B 3/00

(52) U.S. Cl. CPC G01L 9/06; B81B 3/0021; B81B 2201/0264; B81B 2203/0109

(57) ABSTRACT

The present disclosure provides a detection apparatus, a training method and a training apparatus. The detection apparatus includes a plurality of MEMS sensors configured to collect signals to be detected in real time and output sensing signals according to the signals to be detected; a processing module configured to receive the sensing signals of the plurality of MEMS sensors and determine a detection result of the detection apparatus according to the sensing signals of the plurality of MEMS sensors at each sampling time; wherein, there is a predetermined interval duration between two adjacent sampling times, and a sensing signal of each of the MEMS sensors at the current sampling time is related to a signal to be detected at the current sampling time, a sensing signal at the previous sampling time and an attenuation coefficient.

### CROSS-REFERENCE TO RELATED APPLICATION

The present application is a U.S. National Phase Entry of International Application No. PCT/CN2023/114858 having an international filing date of Aug. 25, 2023, the entire content of which is incorporated herein by reference.

### TECHNICAL FIELD

The present disclosure relates to the field of display technologies, and in particular to a detection apparatus, a training method, a training apparatus and a computer-readable storage medium.

### BACKGROUND

A micro electro mechanical system (MEMS) is a new interdisciplinary high-tech research field. Due to the advantages of small size, easy integration, reliable performance and the achievable conversion from non-electrical signal to electrical signal etc., pressure sensors manufactured by MEMS technology have been often used for pressure measurement in consumer, automobile, aerospace, petrochemical and biomedical fields and so on.

### SUMMARY

The present disclosure provides a detection apparatus, including: a plurality of MEMS sensors configured to collect signals to be detected in real time and output sensing signals according to the signals to be detected; a processing module configured to receive the sensing signals of the plurality of MEMS sensors and determine a detection result of the detection apparatus according to the sensing signals of the plurality of MEMS sensors at each sampling time. There is a predetermined interval duration between two adjacent sampling times, and a sensing signal of each of the MEMS sensors at a current sampling time is related to a signal to be detected at the current sampling time, a sensing signal at a previous sampling time and an attenuation coefficient.

In some embodiments, the MEMS sensors include a MEMS pressure sensor.

In some embodiments, a MEMS sensor includes a pressure sensing chamber and a pressure sensing layer located on a side of the pressure sensing chamber along a direction of a depth of the pressure sensing chamber, a maximum deformation of the pressure sensing layer is greater than ⅕ of a thickness of the pressure sensing layer; and a maximum stress of the pressure sensing layer is less than ⅕ of a yield strength of the pressure sensing layer.

In some embodiments, the MEMS sensor includes: a first component including the pressure sensing layer and a plurality of varistors disposed on the pressure sensing layer, the plurality of varistors being connected in series to form a Wheatstone bridge; a second component bonded with the first component and defining the pressure sensing chamber. An orthographic projection of the varistors on the pressure sensing layer within a range of an orthographic projection of the pressure sensing chamber on the pressure sensing layer; and the Wheatstone Bridge is electrically connected with the processing module through the second component to transmit the sensing signal of the MEMS sensor to the processing module.

In some embodiments, the first component further includes a support portion, and the pressure sensing layer is located on a side of the support portion facing the second component. The support portion and the pressure sensing layer are connected as an integral structure.

In some embodiments, the first component further includes a plurality of connectors located on a side of the pressure sensing layer facing the second component; and the plurality of varistors are connected in series through the plurality of connectors.

In some embodiments, a connector includes a connecting wire connecting two adjacent varistors and a bonding pad located on a side of the connecting wire close to the second component.

In some embodiments, the first component further includes a first substrate, the varistors are disposed on the first substrate, the first substrate of the plurality of MEMS sensors is common, and the first substrate is further provided with a first power supply line and a second power supply line.

The plurality of connectors include: a first connector, a second connector and a third connector. The second connector is electrically connected with the first power supply line, the third connector is electrically connected with the second power supply line, and the first connector is electrically connected with the processing module through the second component.

In some embodiments, the second component includes: a second substrate bonded with the first component, a first via being provided on the second substrate; and a first conductive member located on a side of the second substrate facing away from the first component, the first conductive member being electrically connected with the first connector through a first transmission member, at least a part of the first transmission member being located in the first via.

The first conductive member electrically connects the first connector with the processing module.

In some embodiments, the plurality of MEMS sensors include a main sensor and a plurality of slave sensors, and a second via and a third via are further provided on a second substrate of the main sensor.

The second component of the main sensor further includes: a second conductive member located on a side of the second substrate facing away from the first component and electrically connected with the second connector through a second transmission member, at least a part of the second transmission member being located in the second via; and a third conductive member located on a side of the second substrate facing away from the first component and electrically connected with the third connector through a third transmission member, at least a part of the third transmission member being located in the third via.

The second conductive member is electrically connected with a first power supply end, and the third conductive member is electrically connected with a second power supply end.

In some embodiments, the MEMS sensor includes a second connector for receiving a first power supply signal and a third connector for receiving a second power supply signal.

The plurality of MEMS sensors includes a main sensor and a plurality of slave sensors, the main sensor and the plurality of slave sensors are arranged and connected in a topology structure in which second connectors of any two connected sensors are connected, and third connectors of any two connected MEMS sensors o are connected.

In some embodiments, the topology structure includes any one of a star topology structure, a ring topology structure, a tree topology structure, and a bus topology structure.

In the star topology structure, the plurality of slave sensors are located at a side of a first center line of the main sensor and are arranged in a row; in the ring topology structure, the plurality of slave sensors are arranged around the main sensor; in the tree topology structure, the plurality of slave sensors are located at a side of the first center line of the main sensor and arranged in a plurality of rows, and in two adjacent rows, the number of the slave sensors in a row close to the main sensor is less than the number of the slave sensors in a row far from the main sensor; in the bus topology structure, the plurality of slave sensors are located at the same side of a second center line of the main sensor and distributed at opposite sides of the first center line of the main sensor.

The first center line intersects with the second center line.

In some embodiments, the processing module includes: a signal amplification sub-module configured to amplify the output signals of the plurality of MEMS sensors to obtain amplified signals of the plurality of MEMS sensors; an analog-to-digital conversion sub-module configured to perform analog-to-digital conversion on the output signals of the signal amplification sub-module to obtain analog-to-digital conversion results of the plurality of MEMS sensors; and an analysis module configured to determine a detection result of the detection apparatus based on the analog-to-digital conversion results of the plurality of MEMS sensors.

In some embodiments, the analysis module includes: a monitor configured to determine a target signal range based on the analog-to-digital conversion results of the plurality of MEMS sensors, and determine whether an error result exists in the analog-to-digital conversion results of the plurality of MEMS sensors according to the target signal range; and an algorithm processor configured to correct the error result if the error result exists, and perform analyzing and processing to determine the detection result of the detection apparatus according to the corrected result and the analog-to-digital conversion results of other MEMS sensors.

The present disclosure provides a training method of the detection apparatus as described in any one of the above embodiments, including: creating a model of the detection apparatus; acquiring a training set including a plurality of sample detection signals; inputting the sample detection signals into the model to obtain sample output signals; adjusting an excitation condition of the MEMS sensors in the model and the predetermined interval duration of a processor in the model according to the difference between the sample output signals and a target output signal, until a target training condition is satisfied.

In some embodiments, the excitation condition includes a first power supply voltage and a second power supply voltage provided to the MEMS sensors.

The present disclosure provides a training apparatus for a detection apparatus, including: a model creation module configured to create a model of the detection apparatus; a training set acquisition module configured to acquire a training set including a plurality of sample detection signals; and a training module configured to input the sample detection signals into the model to obtain sample output signals, and adjust an excitation condition of MEMS sensors in the model and a predetermined interval duration of a processor in the model according to the difference between the sample output signals and a target output signal, until a target training condition is satisfied.

The present disclosure provides a computer-readable storage medium having stored thereon a computer program, wherein when the program is executed by a processor, the method described in the above embodiments is implemented.

### BRIEF DESCRIPTION OF DRAWINGS

The drawings are used for providing a further understanding of the present disclosure and constitute a part of the specification, and are used for explaining the present disclosure together with the following specific implementations but do not constitute limitations on the present disclosure. In the drawings:

FIG. 1 is a schematic diagram of a structure of a detection apparatus provided in an embodiment of the present disclosure.

FIG. 2A is a schematic diagram of input and output of a detection apparatus provided in an embodiment of the present disclosure.

FIG. 2B is a schematic diagram of an operating principle of a sensor provided in an embodiment of the present disclosure.

FIG. 3 is a schematic diagram of a structure of a sensor provided in an embodiment of the present disclosure.

FIG. 4A is a cross-sectional view of a first component provided in an embodiment of the present disclosure.

FIG. 4B is a top view of a first component provided in an embodiment of the present disclosure.

FIG. 4C is a cross-sectional view of another first component provided in an embodiment of the present disclosure.

FIG. 4D is a top view of another first component provided in an embodiment of the present disclosure.

FIG. 5A is a cross-sectional view of a second component provided in an embodiment of the present disclosure.

FIG. 5B is a top view of a second component provided in an embodiment of the present disclosure.

FIG. 6 is a schematic diagram of bonding of a second component and a first component provided in an embodiment of the present disclosure.

FIG. 7 is a schematic diagram of wiring of a plurality of first components provided in an embodiment of the present disclosure.

FIG. 8 is a schematic diagram of topology structures that a plurality of sensors can be arranged in provided in an embodiment of the present disclosure.

FIG. 9 is a block diagram of a detection apparatus provided in an embodiment of the present disclosure.

FIGS. 10A to 10G are process flow diagrams of a sensor provided in an embodiment of the present disclosure.

FIG. 11 is a schematic diagram of a structure of a training apparatus of a detection apparatus provided in an embodiment of the present disclosure.

### DETAILED DESCRIPTION

Specific implementations of the present disclosure are described in detail below with reference to the accompanying drawings. It should be understood that the specific implementations described herein are only intended to illustrate and explain the present disclosure and are not intended to limit the present disclosure.

In the specification, for convenience, expressions “central”, “above”, “below”, “front”, “back”, “vertical”, “horizontal”, “top”, “bottom”, “inside”, “outside”, etc., indicating orientational or positional relationships are used to illustrate positional relationships between the composition elements with reference to the drawings, which are only for convenience of describing the specification and simplifying the description and are not intended to indicate or imply that the involved devices or elements must have specific orientations, are structured and operated with the specific orientations, and thus cannot be understood as limitations on the present disclosure. The positional relationships between the composition elements may be changed as appropriate according to a direction in which each composition element is described. Therefore, appropriate replacements based on situations are allowed, which is not limited to the expressions in the specification.

Unless otherwise defined, technical terms or scientific terms used in the embodiments of the present disclosure shall have common meanings understood by those with ordinary skills in the art to which the present disclosure pertains. The “first”, “second” and similar terms used in the present disclosure do not indicate any order, quantity, or importance, but are used only for distinguishing different components. Likewise, wording such as “include”, “contain” and the like mean that elements or objects appearing before the wording cover elements or objects listed after the wording and their equivalents, but do not exclude other elements or objects. The terms “installation”, “connect with” and “connection” should be understood in a broad sense. For example, a connection may be a fixed connection, or a detachable connection, or an integral connection; it may be a mechanical connection or an electrical connection; it may be a direct connection, or an indirect connection through an intermediate, or internal communication between two elements. Those of ordinary skills in the art can understand specific meanings of the above terms in the present disclosure according to specific situations.

With the development of the Internet of Things era, the research of simulating neural network algorithm using various sensors is gradually carried out at home and abroad, in order to provide a better solution for edge computing. Outstanding achievements have been made in the intelligent research of MEMS sensors in academic circles, which effectively combines the technical advantages of MEMS such as small size, light weight and low power consumption, and preliminarily verifies the feasibility of the application of MEMS intelligent sensors based on neural network algorithm in pattern recognition, time series prediction and other tasks.

However, MEMS sensors are mostly designed as single independent devices, and the achievable nonlinear mapping effect is often only suitable for relatively simple tasks. This poses great constraints on further leveraging the technical advantages of MEMS sensors, achieving stronger computing power, enhancing their stronger market application possibilities, and providing strong technical support for the future Internet of Things era of “Intelligent internet of all things”.

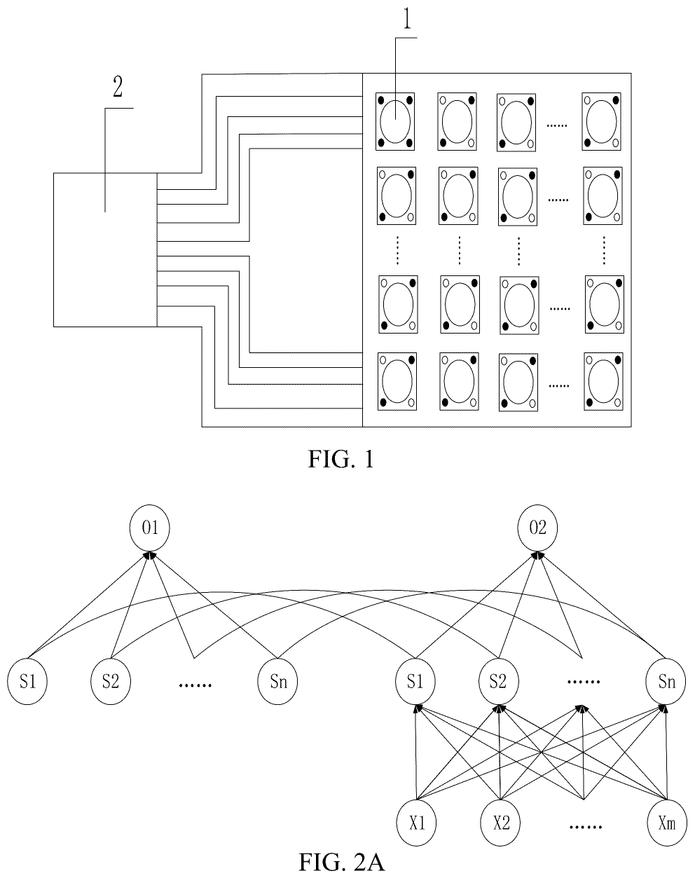

FIG. 1 is a schematic diagram of a structure of a detection apparatus provided in an embodiment of the present disclosure. As shown in FIG. 1, the detection apparatus includes a plurality of sensors 1 and a processing module 2. The sensors 1 are configured to collect signals to be detected in real time and output sensing signals according to the signals to be detected. The signals to be detected may be signals to be detected in nature, for example, a pressure signal, a sound signal or other signals. The sensors 1 are MEMS sensors.

The processing module 2 is configured to receive sensing signals of the plurality of sensors 1 and determine the detection result of the detection apparatus according to sensing signals of the plurality of sensors 1 at each sampling time.

The sensors 1 can collect the signals to be detected in real time, and the processing module 2 can process sensing signals generated by the sensors 1 at multiple sampling times instead of all the sensing signals generated by the sensors 1. There is a predetermined interval duration between two adjacent sampling times, and a sensing signal of each sensor 1 at the current sampling time is related to a signal to be detected at the current sampling time, a sensing signal at the previous sampling time and an attenuation coefficient, and the attenuation coefficient is related to device intrinsic parameters of the sensor 1.

The device intrinsic parameters of the sensor 1 are parameters related to device structure of the sensor 1 itself. For example, if the sensor 1 is a pressure sensor, the device intrinsic parameters of the sensor 1 may include parameters such as the thickness, the sensing area of a pressure film of the pressure sensor.

The attenuation coefficient can characterize the nonlinearity of the sensor 1. The so-called “nonlinearity” is a concept opposite to “linearity”. “Linearity” means that a sensing signal (i.e., an output signal) of a sensor 1 at the current sampling time is only related to the current signal to be detected (i.e., an input signal), but is independent of an output signal at the previous sampling time. “Nonlinearity” means that a sensing signal of a sensor 1 at the current sampling time is not only related to a signal to be detected at the current sampling time, but also related to a sensing signal at the previous sampling time. The larger the attenuation coefficient, the greater the influence of a sensing signal at the current sampling time on a sensing signal at the previous sampling time, the higher the nonlinearity of the sensor 1. The smaller the attenuation coefficient, the smaller the influence of a sensing signal at the current sampling time on a sensing signal at the previous sampling time, and the lower the nonlinearity of the sensor 1.

The detection result of the detection apparatus may include: the current use situation of the detection apparatus. For example, taking a pressure detection apparatus as an example, the processing module can obtain a pressure of each pressure sensor by obtaining sensing signals of the plurality of pressure sensors, and then determine the pressure state of the pressure detection apparatus. For example, the pressure detection apparatus may be an apparatus worn on a human body and the processing module 2 can determine the posture and movement of the human body by performing force analysis. The processing module 2 can determine the detection result according to the classification algorithm.

A detection apparatus provided in an embodiment of the present disclosure includes a plurality of sensors 1, and the processing module 2 processes according to sensing signals output by the plurality of sensors 1 to determine the detection result, so that more reliable and accurate sensing results can be obtained by fusing the sensing signals of the plurality of sensors 1, and the fault tolerance and environmental adaptability of the detection apparatus can be improved. Since a parallel structure design is adopted among the plurality of sensors 1 in the detection apparatus, the operation calculation speed of the detection apparatus for detecting a signal to be detected can also be improved.

In addition, a sensing signal of any one of the plurality of sensors 1 at the current sampling time is not only related to a signal to be detected at the current sampling time, but also affected by a sensing signal at the previous sampling time. Therefore, the sensors 1 provided by the present disclosure each have higher nonlinearity and can be used as neurons of a neural network. The plurality of sensors 1 are coupled with each other, which can make the nonlinear mapping of the signal to be detected stronger, thereby improving the classification and recognition ability of the neural network, and further making the detection apparatus have better sensing effect, higher precision and stronger calculation force.

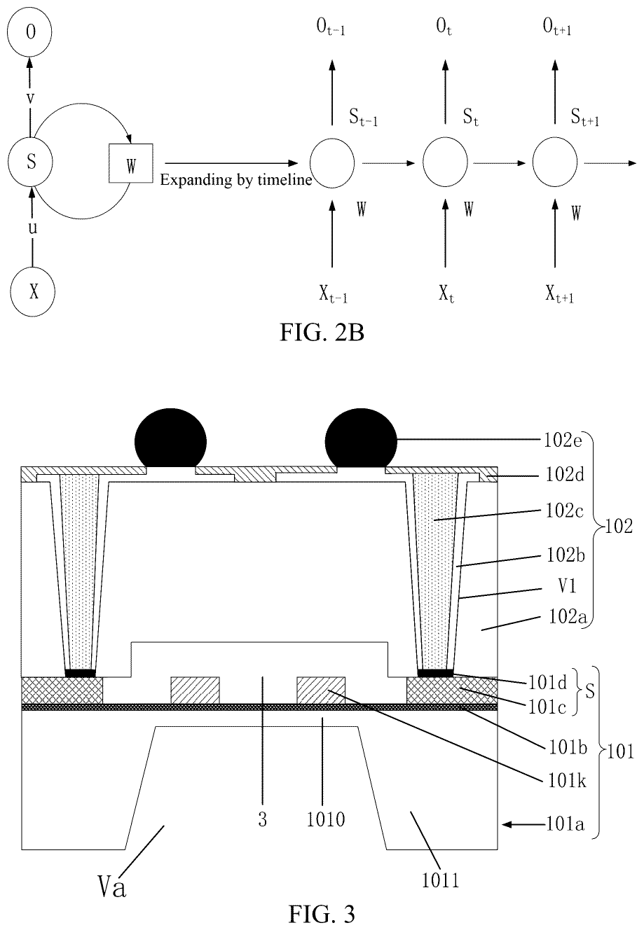

FIG. 2A is a schematic diagram of an input and output principle of the detection apparatus provided in the embodiment of the present disclosure, and FIG. 2B is a schematic diagram of a working principle of a sensor 1 provided in the embodiment of the present disclosure. A plurality of sensors in FIG. 2A and FIG. 2B can improve the detection effect of the detection apparatus by realizing the hardware of the neural network.

For example, when the neural network is a cyclic neural network, as shown in FIGS. 2A and 2B, X=[X1, X2, X3 . . . . Xm] represents a signal to be detected by the detection apparatus, that is, an input layer in the cyclic neural network. S=[S1, S2, S3 . . . . Sn] represents the detection apparatus, that is, a hidden layer in the neural network. S1, S2, S3 . . . . Sn represent a plurality of sensors 1 in the detection apparatus, that is, neurons in a cyclic neural network. O=[O1, O2, O3 . . . . Om] represents the detection result of the detection apparatus, that is, an output layer in the cyclic neural network.

As shown in FIG. 2B, Sₜ=f (U*Xₜ+W*Xₜ₋₁) represents sensing signals of the sensors 1 of the detection apparatus at the sampling time t. A sensing signal Sₜ at the current sampling time is generated according to a signal to be detected at the current sampling time, a sensing signal at the previous sampling time and the attenuation coefficient. Oₜ=g (V*Sₜ) represents a detection result of the processing module 2 at the sampling time t. W represents the attenuation coefficient, that is, the feedback weight in the cyclic neural network.

For an input signal at a certain time, the plurality of sensors can realize multi-point data acquisition and mapping, and the sensing signal of each sensor is not only affected by a signal to be measured at the current sampling time, but also affected by the state accumulation of the sensor, so that more complex signal transmission and nonlinear state coupling can be realized, and the overall high-dimensional mapping ability of the detection apparatus can be improved.

FIG. 3 is a schematic diagram of a structure of a sensor 1 provided in an embodiment of the present disclosure. As shown in FIG. 3, in the embodiment of the present disclosure, the sensor 1 provided in the embodiment of the present disclosure includes a MEMS pressure sensor. The MEMS pressure sensor is a kind of micro electro mechanical system, which can measure pressure and convert it into an electrical signal for output. The MESM pressure sensor has the characteristics of small volume, light weight, low cost, high reliability, suitable for batch production, easy integration and intelligent realization.

The MESM pressure sensor includes a first component 101 and a second component 102. The second component 102 may be an integrated circuit (ACIS) chip. The first component 101 is used for converting the sensed pressure into an electrical signal, and the second component 102 is used for outputting the electrical signal output by the first component 101 to the processing module 2. The first component 101 and the second component 102 are electrically connected by anodic bonding.

In some embodiments, as shown in FIG. 3, the sensor 1 includes a pressure sensing chamber 3 and a pressure sensing layer 1010 located on a side of the pressure sensing chamber 3 along a direction of the depth of the pressure sensing chamber, a maximum deformation of the pressure sensing layer 1010 being greater than ⅕ of a thickness of the pressure sensing layer 1010. A maximum stress of the pressure sensing layer 1010 is less than ⅕ of a yield strength of the pressure sensing layer 1010.

It should be noted that the maximum deformation refers to the deformation of the pressure sensing layer 1010 when a maximum pressure value of a detection range of the sensor 1 is applied to the pressure sensing layer 1010, and the deformation is specifically a displacement of the pressure sensing layer 1010 in a thickness direction of the pressure sensing layer 1010.

The yield strength of the pressure sensing layer 1010 refers to the ability of the pressure sensing layer 1010 to withstand external forces, and the yield strength of the pressure sensing layer 1010 is also used to measure the ability of the material of the pressure sensing layer 1010 to withstand pressure without deformation after being acted by external forces.

In the embodiment of the present disclosure, the maximum deformation of the pressure sensing layer 1010 is larger than ⅕ of the thickness of the pressure sensing layer 1010, which can ensure that the pressure sensing layer 1 cannot recover from the maximum deformation to a natural state (i.e., the unstressed state) within the interval between two adjacent sampling times, so as to ensure that a sensing signal of the sensor 1 at the current sampling time can be affected by a sensing signal at the previous sampling time. The maximum stress of the pressure sensing layer 1010 is less than ⅕ of the yield strength of the pressure sensing layer 1010, which can prevent the damage of the pressure sensing layer 1010.

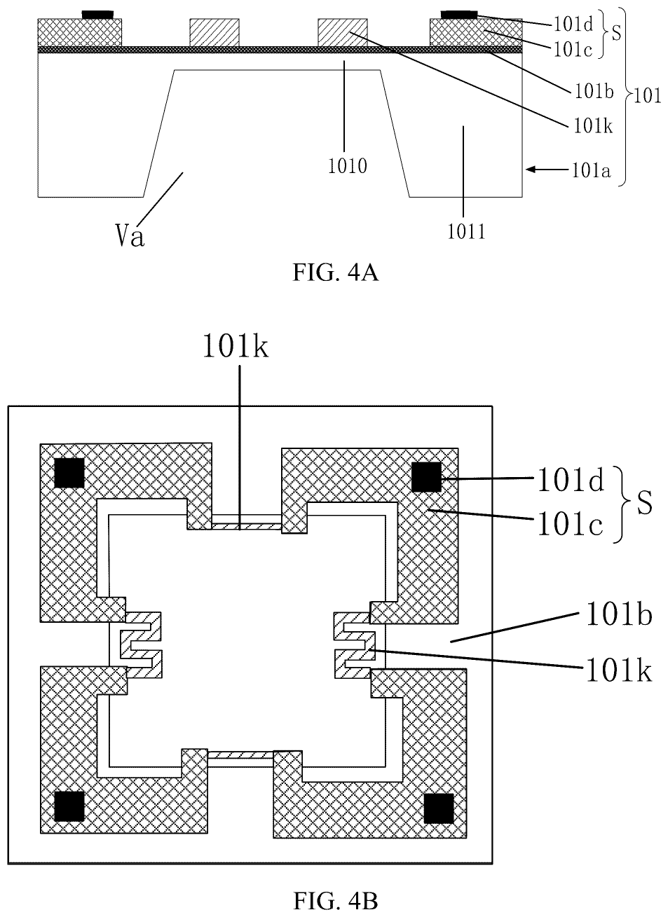

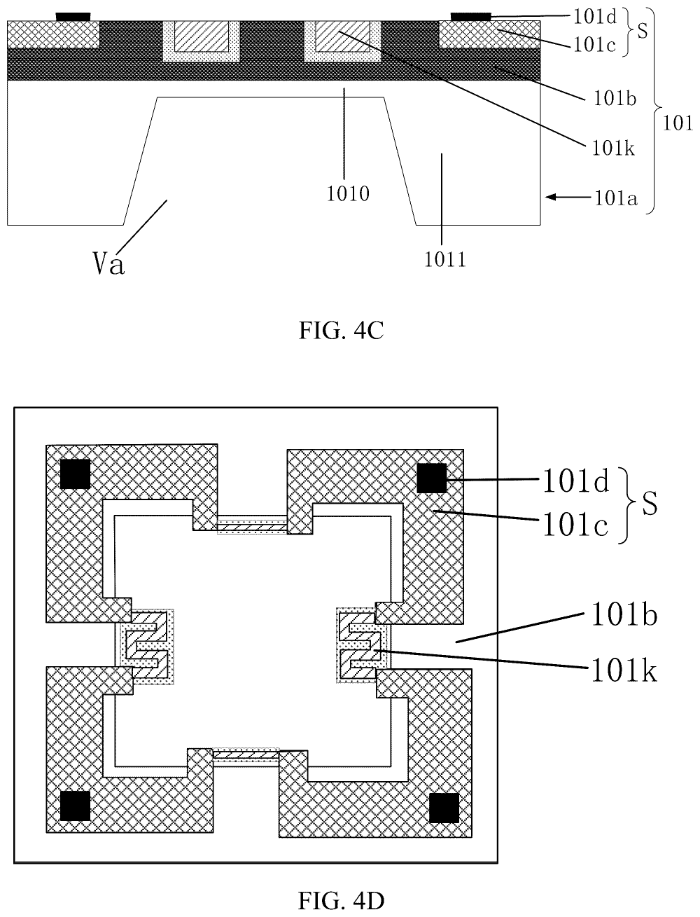

FIG. 4A is a cross-sectional view of a first component provided in an embodiment of the present disclosure, and FIG. 4B is a top view of a first component provided in an embodiment of the present disclosure. As shown in FIGS. 3-4B, in some embodiments, the sensor 1 includes a first component 101 and a second component 102. The first component 101 further includes a support portion 1011, and a pressure sensing layer 1010 is positioned on a side of the support portion 1011 facing the second component 102. The support portion 1011 and the pressure sensing layer 1010 are connected as an integral structure, and this integral structure is referred to as a first substrate 101a.

As shown in FIGS. 3 to 4B, a side of the first substrate 101a facing away from the second component 102 is formed with a groove Va. At least a part of the pressure sensing layer 1010 is located between a surface of the first substrate 101a facing the second component 102 and a bottom surface of the groove Va.

The first substrate 101a may be a silicon substrate.

As shown in FIGS. 3 to 4B, a plurality of varistors 101d are provided on the pressure sensing layer 1010 and the plurality of varistors 101d are connected in series to form a Wheatstone bridge. The shape of the varistors 101d may be a strip shape, a curved shape or the like and may be provided according to actual needs. In one example, the shapes of the plurality of varistors 101d may not be identical, for example two varistors 101d are strip-shaped and the remaining two varistors 101d are bent-shaped.

In some embodiments, as shown in FIGS. 4A and 4B, the first component 101 further includes a plurality of connectors S. The plurality of connectors S are located on a side of the first substrate 101a facing the second component 102. The plurality of varistors 101d are connected in series through the plurality of connectors S.

In some embodiments, as shown in FIGS. 4A and 4B, the connector S includes a connecting wire 101c connecting two adjacent varistors 101d and a bonding pad 101d located on a side of the connecting wire 101c close to the second component 102.

In some embodiments, as shown in FIG. 3, the first component 101 may also include a lightly doped layer 101b, and the varistors 101d and the connectors S are all located on a side of the lightly doped layer 101b facing the second component 102. The lightly doped layer 101b may be formed by lightly doping a silicon base substrate. The connecting wire 101c may be formed after heavily doping a silicon base substrate and performing a patterning process.

In one example, the bonding pad 101d may be a metal pad. Specifically a metal layer may be formed by a sputtering process, and the metal layer may be patterned to form the metal pad.

In FIGS. 4A to 4B, the varistors 101d may be arranged in the same layer as the connecting wire 101c. The varistors 101d and the connecting wire 101c are formed by heavy doping and patterning processes.

FIG. 4C is a cross-sectional view of another first component provided in an embodiment of the present disclosure, and FIG. 4D is a top view of another first component provided in an embodiment of the present disclosure. The first component shown in FIGS. 4C and 4D is similar to FIGS. 4A and 4B except that in FIGS. 4C and 4D, the varistor 101d may be specifically a PN junction. The different connecting wires 101c and the different PN junctions are spaced apart by the lightly doped layer 101b.

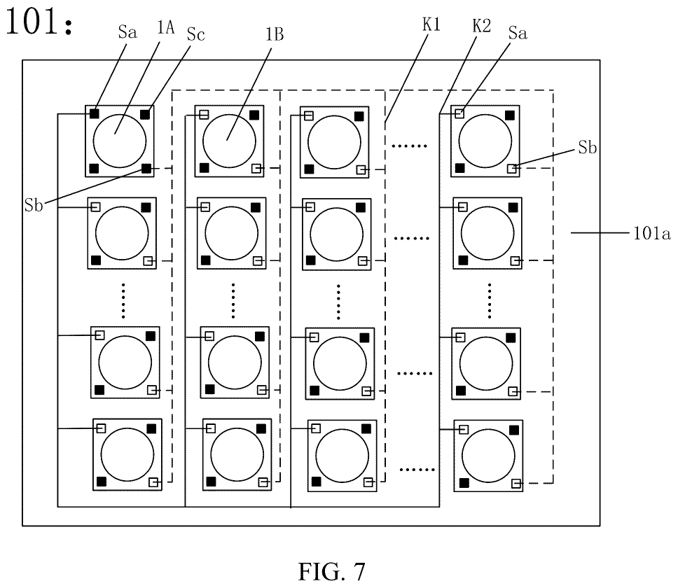

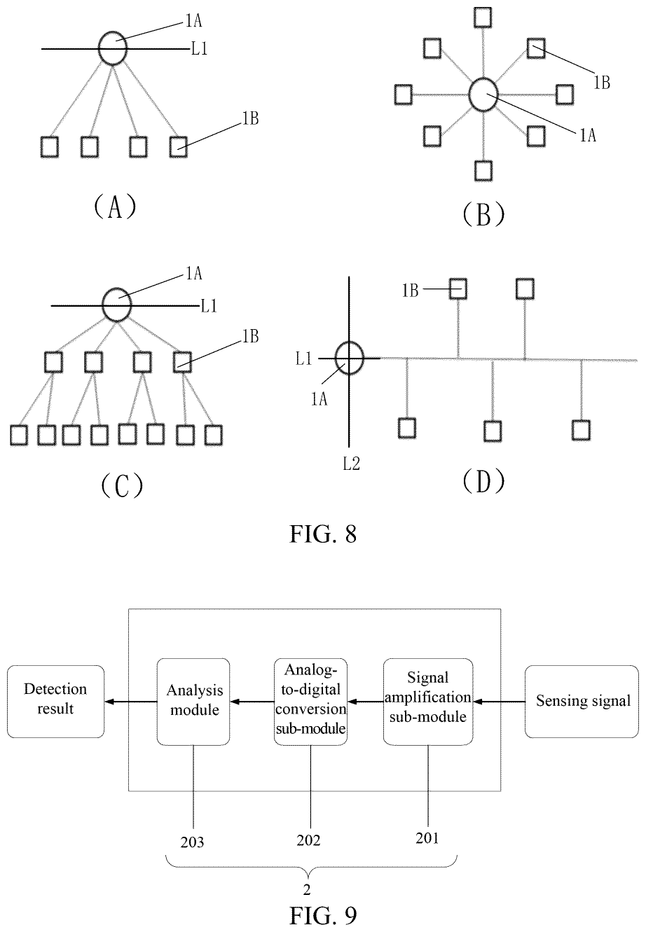

FIG. 7 is a schematic diagram of wiring of a plurality of first components provided in an embodiment of the present disclosure. In some embodiments, as shown in FIG. 7, a first substrate 101a of a plurality of sensors 1 is shared, and a first power supply line K1 and a second power supply line K2 are also provided on the first substrate 101a. One of the first power supply line K1 and the second power supply line K2 is a driving signal line, and the other is a ground line.

As shown in FIG. 3, the plurality of connectors S include a second connector Sa, a third connector Sb and a first connector Sc. The second connector Sa is electrically connected to the first power supply line K1, the third connector Sb is electrically connected to the second power supply line K2, and the first connector Sc is electrically connected to the processing module 2 by the second component 102 to transmit the output signal of the pressure sensor 1 to the processing module 2.

It should be noted that the second connector Sa is connected to the first power supply line K1. Alternatively, a connecting wire 101c of the second connector Sa is connected to the first power supply line K1 or a bonding pad 101d of the second connector Sa is connected to the first power supply line K1. Alternatively, both the connecting wire 101c and the bonding pad 101d in the second connector Sa are connected to the first power supply line K1. The first power supply line K1 may be in the same layer as the connecting wire 101c or the bonding pad 101d, or the first power supply line K1 includes two sub-layers which are in the same layer as the connecting wire 101c and the bonding pad 101d, respectively.

Similarly, the third connector Sb is connected to the second power supply line K2. Alternatively, the connecting wire 101c of the third connector Sb is connected to the second power supply line K2, or the bonding pad 101d of the third connector Sb is connected to the second power supply line K2. Alternatively, both the connecting wire 101c and the bonding pad 101d in the third connector Sb are connected to the second power supply line K2. The second power supply line K2 may be in the same layer as the connecting wire 101c or the same layer as the bonding pad 101d, or the second power supply line K2 includes two sub-layers which are in the same layer as the connecting wire 101c and the bonding pad 101d, respectively.

It should be noted that “disposed in the same layer” in this disclosure means that two structures are formed by the same material layer through patterning process, so they are in the same layer in lamination relationship. But this does not mean that the distance between them and the same reference plane must be the same.

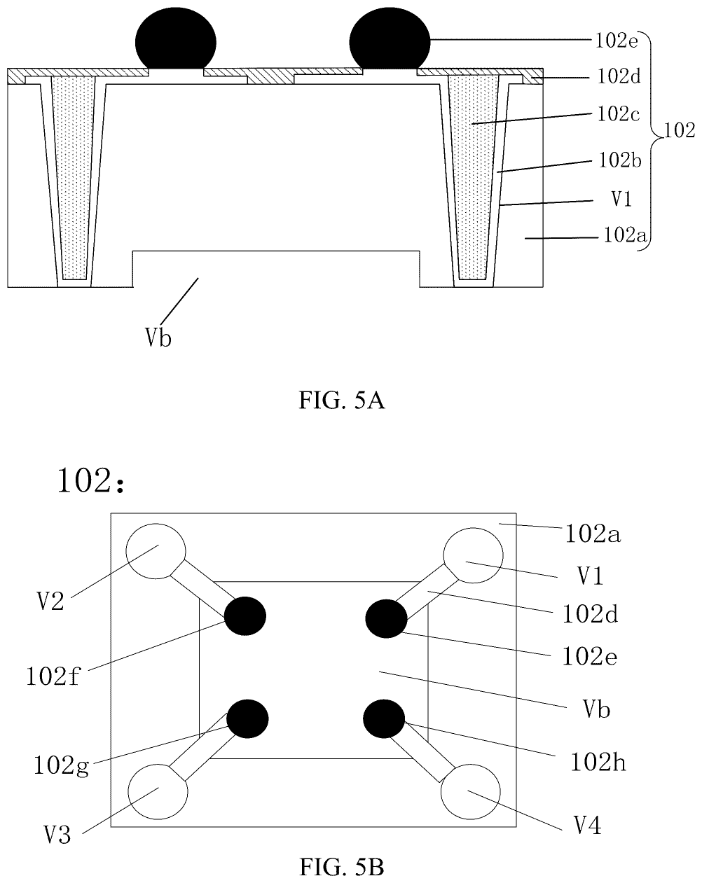

FIG. 5A is a cross-sectional view of a second component provided in an embodiment of the present disclosure, and FIG. 5B is a top view of a second component provided in an embodiment of the present disclosure. As shown in FIGS. 5A and 5B, in some embodiments, the second component 102 includes a second substrate 102a, and a first conductive member 102e. The first conductive member 102e may be a tin ball and has good conductivity. The second substrate 102a is bonded to the first component 101, and the second substrate 102a is provided with a first via V1.

The first conductive member 102e is located on a side of the second substrate 102a facing away from the first component 101 and is electrically connected to the first connector Sc through a first transmission member 102b. At least a part of the first transmission member 102b is located in the first via V1. The first conductive member 102e electrically connects the first connector Sc with the processing module 2.

A portion of the first transmission member 102b located in the first via V1 may be a metal material, and may be located on a sidewall of the first via V1 without completely filling the first via V1. In this case, a filling portion 102c may be provided in the first via V1. The filling portion 102c may include, but is not limited to, a conductive material such as a metal, a glass paste. Alternatively, the filling portion 102c may also be an insulating material.

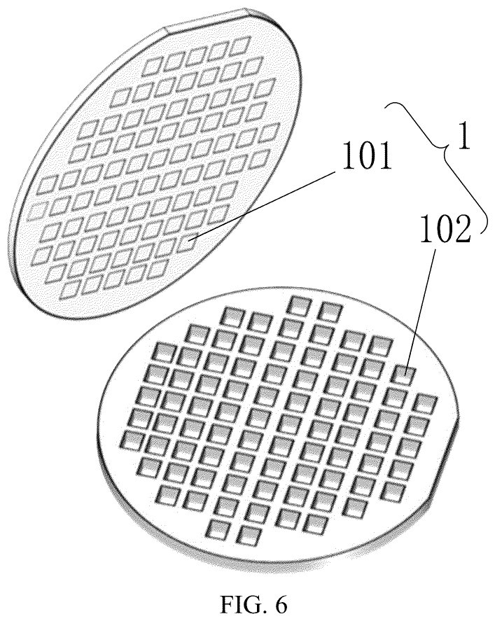

FIG. 6 is a schematic diagram of a bonding of a second component and a first component provided in an embodiment of the present disclosure. As shown in FIGS. 3 and 6, the second component 102 is bonded to the first component 101 and defines a pressure sensing chamber 3. An orthographic projection of the varistors 101d on the pressure sensing layer 1010 is within a range of an orthographic projection of the pressure sensing chamber 3 on the pressure sensing layer 1010.

As shown in FIGS. 5B and 7, in some embodiments, the plurality of sensors 1 includes a main sensor 1A and a plurality of slave sensors 1B, and a second via V2 and a third via V3 are also provided on a second substrate 102a of the main sensor 1A.

The second component 102 of the main sensor 1A includes a second conductive member 102f and a third conductive member 102g in addition to the first conductive member 102e described above. The second conductive member 102f is located on a side of the second substrate 102a facing away from the first component 101 and is electrically connected to the second connector Sa through a second transmission member 102m. At least a part of the second transmission member 102m is located in the second via V2.

As shown in FIGS. 5A, 5B and 7, the third conductive member 102g is located on a side of the second substrate 102a facing away from the first component 101 and is electrically connected to the third connector Sb through a third transmission member 102n. At least a part of the third transmission member 102n is located in the third via V3. The second conductive member 102f is electrically connected to a first power supply end and the third conductive member 102g is electrically connected to a second power supply end.

The first power supply end and the second power supply end are ports for supplying power supply signals to the plurality of sensors 1. For example, the plurality of sensors 1 and the processing module 2 may be integrated on the same printed circuit board (PCB), and the first power supply end and the second power supply end may be power supply ports provided on the printed circuit board.

In an embodiment of the present disclosure, the main sensor 1A may include a first conductive member 102e, a second conductive member 102f, and a third conductive member 102g, while the slave sensor 1B may include the first conductive member 102e without including the second conductive member 102f and the third conductive member 102g. In this case, the signal of the first power supply end may be supplied to the main sensor 1A by the second conductive member 102f and to the respective slave sensors 1B by the first power supply line K1. The signal of the second power supply end may be supplied to the main sensor 1A by the third conductive member 102g and to the respective slave sensors 1B by the second power supply line K2. This arrangement does not need to arrange the second conductive member 102f and the third conductive member 102g in the slave sensor 1B, thereby simplifying the structure of the sensor 1, and can optimize the wiring arrangement and improve the fatigue resistance and reliability of the sensor 1.

In some embodiments, the main sensor 1 and the plurality of slave sensors 1 may be arranged according to actual needs, for example in an array (i.e. in rows and columns), or be arranged and connected in a topology structure in which the second connector Sa of any two connected sensors 1 may be connected by a first power supply line K1, and the third connector Sb of any two connected sensors 1 may be connected by a second power supply line K2.

FIG. 8 is a schematic diagram of topology structures that a plurality of sensor can be arranged in provided in an embodiment of the present disclosure. As shown in FIG. 8, in some embodiments, the topology structure includes any one of a star topology structure, a ring topology structure, a tree topology structure and a bus topology structure. Specifically, as shown in FIG. 8 (A), a plurality of sensors in the detection apparatus may be arranged in a star topology structure. One sensor 1 is selected from the plurality of sensors as the main sensor 1A, and the remaining sensors 1 are all the slave sensors 1B, and the plurality of slave sensors 1B are located at a side of a first center line L1 of the main sensor 1A and arranged in a row or a column. All of the slave sensors 1B are connected to the main sensor 1A through a first power supply line K1 and a second power supply line K2 respectively. The first center line L1 is a straight line passing through the center of the main sensor 1A and parallel to the pressure sensing layer 1010.

As shown in FIG. 8 (B), the plurality of sensors 1 in the detection apparatus may be arranged in a ring topology structure. One sensor 1 of the plurality of sensors 1 serves as a main sensor 1A, and the remaining sensors 1 serve as slave sensors 1B. The main sensor 1A is surrounded by a plurality of slave sensors 1B, and all of the slave sensors 1B are connected to the main sensor 1A through a first power supply line K1 and a second power supply line K2, respectively.

Specifically, as shown in FIG. 8 (C), the plurality of sensors 1 in the detection apparatus may be arranged in a tree topology structure. One sensor 1 of the plurality of sensors 1 serves as a main sensor 1A, and the remaining sensors 1 serve as slave sensors 1B. The plurality of slave sensors 1B in the tree topology structure are located at one side of a first center line L1 of the main sensor 1A and are arranged in a plurality of rows. In two adjacent rows, the number of slave sensors 1B in a row close to the main sensor 1A is smaller than the number of slave sensors 1B in a row far away from the main sensor 1A.

The main sensor 1A is connected to each slave sensor 1B in a first row through a first power supply line K1 and a second power supply line K2. In the plurality of slave sensors 1B, each slave sensor 1B in the previous row is connected to at least two slave sensors 1B in the next row through a first power supply line K1 and a second power supply line K2.

As shown in FIG. 8 (D), the plurality of sensors 1 in the detection apparatus may be arranged in a bus topology structure. Specifically, the plurality of slave sensors 1B in the bus topology structure are located at the same side of a second center line L2 of the main sensor 1A and are distributed at opposite sides of the first center line L1 of the main sensor 1A. The first center line L1 intersects the second center line L2. For example, the first center line L1 is perpendicular to the second center line L2. The plurality of sensors 1 in the detection apparatus in the present disclosure may be arranged in a plurality of topology structures and are not specifically limited herein.

It should be noted that, among the plurality of topology structures shown in FIG. 8, each circular structure or square structure represents one sensor, and the interconnecting wire between the circular structure and the square structure represents RDL (ReDistribution Layer) traces. The circular structure represents a main sensor (including driving, grounding and two signal outputs) connected with an external electrical signal realized by the second component 102, and the square structure is a slave sensor, which can realize electrical signal interconnection by different connection modes (topology structures) with the main sensor, so that each slave sensor does not need to be externally connected with a driving power supply signal and a grounding signal by the second component 102.

In a practical application, the specific configuration can be selected according to an application scenario of the detection apparatus, which is beneficial to improve the detection accuracy of the processing module. For example the detection apparatus may be applied to a writing board in which case a plurality of sensors 1 may be arranged in an array. For another example, the detection apparatus may be used in a wearable device in which case the plurality of sensors 1 may be arranged according to the topology structure and a specific topology structure may be selected according to a wearing position of a wearable device.

The present disclosure provides a manufacturing method of a sensor, which includes the following steps:

S1, making a first component.

S2, making a second component, and bonding the first component and the second component.

The first component 101 and the second component 102 can be bonded by anodic bonding.

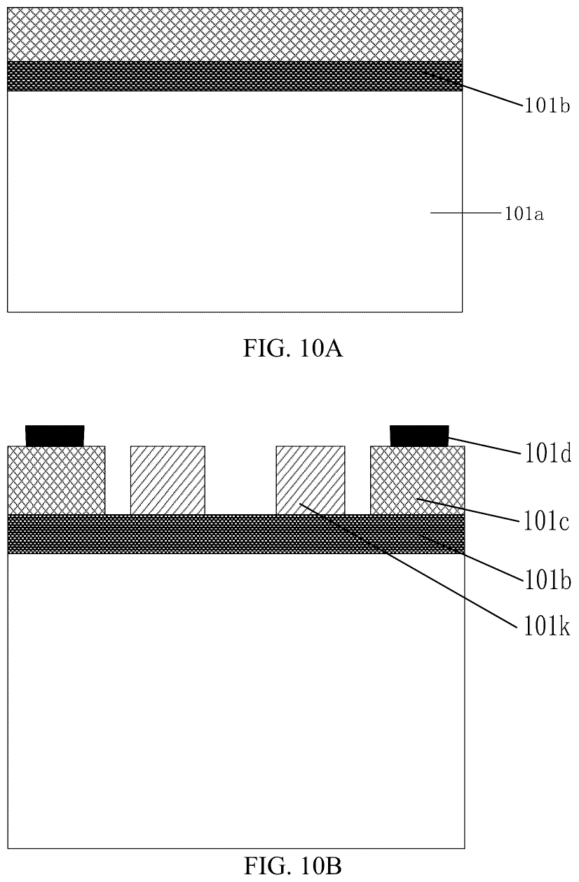

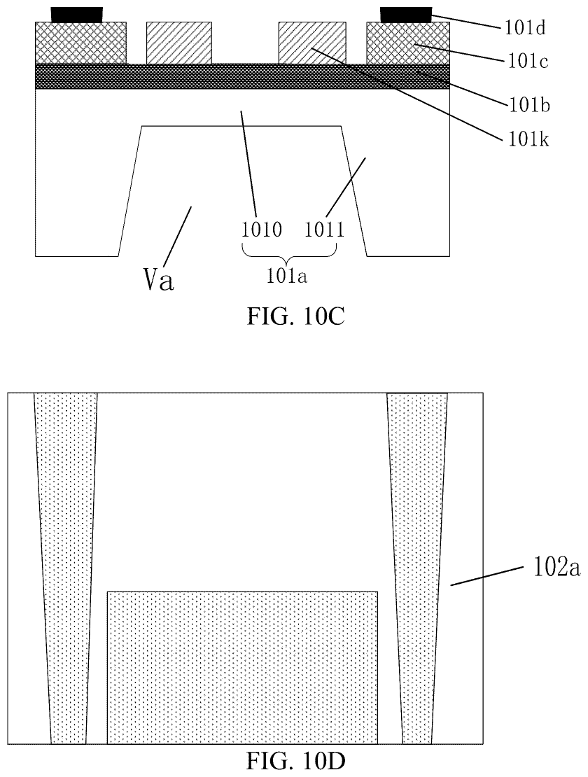

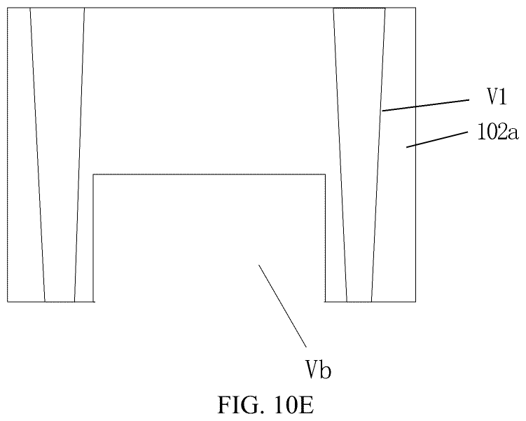

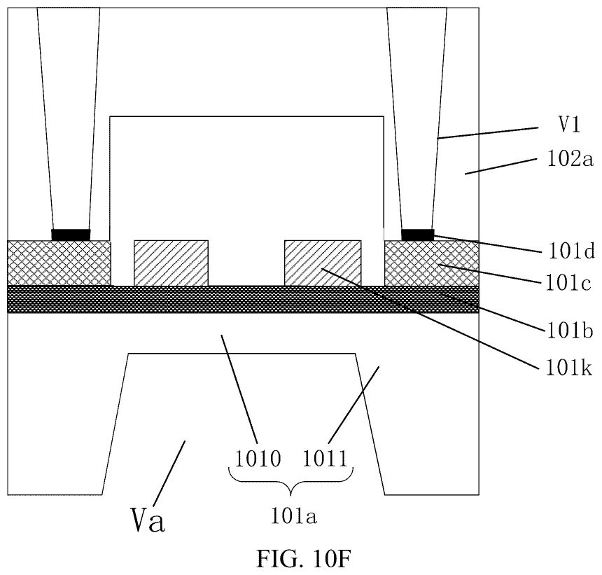

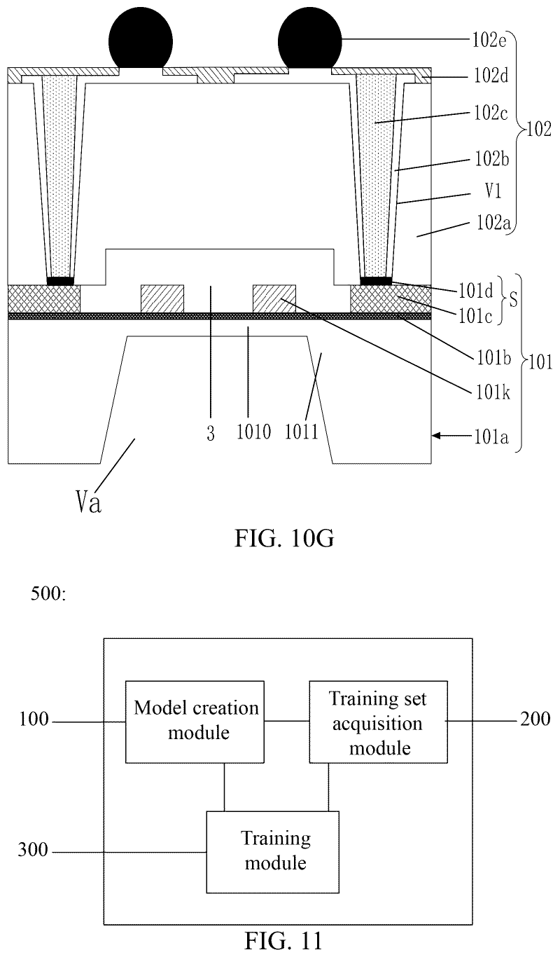

FIGS. 10A to 10G are process flow diagrams of a sensor provided in an embodiment of the present disclosure. As shown in FIGS. 10A to 10G, in some embodiments, step S1 includes the following steps:

S10, as shown in FIG. 10A, providing a first substrate 101a. The material of the first substrate 101a can be monocrystalline silicon, which is a high-purity silicon material. The first substrate 101a made of monocrystalline silicon has the advantages of small coefficient of thermal expansion, high mechanical strength and the like.

S11, performing n-type light doping on the first substrate 101a to form an n-type lightly doped layer 101b.

The n-type lightly doped layer has lower doping impurity concentration, higher carrier mobility and more uniform electron velocity distribution in the doped layer in this doping manner, so it has better conductivity and lower resistivity.

S12, as shown in FIG. 10B, forming a plurality of connecting wires 101c. The n-type lightly doped layer may be heavily doped and a plurality of connecting wires 101c and a plurality of varistors 101d may be formed by a patterning process.

S13, as shown in FIG. 10B, forming a bonding pad on the connecting wires 101c. Each connecting wire 101c and a corresponding bonding pad 101d constitute a connector.

S14, as shown in FIG. 10C, etching a surface of the first substrate 101a facing away from the connecting wires, thereby forming a groove Va.

In some embodiments, Step S2 includes the following steps:

S20, as shown in FIG. 10D, providing a second substrate 102a. The material of the second substrate 102a may be glass. Positions on the second substrate 102 where vias and recessed structures are to be formed are processed using a laser modification process.

S21, as shown in FIG. 10E, forming a via and a recessed structure Vb on the second substrate 102a by a wet etching process.

For the main sensor 1A, the plurality of vias may include a first via V1 a second via and a third via. For the slave sensor 1B, the formed via may include only the first via V1.

In some embodiments, the thinning and planarization of the second substrate 102a in the second component 102 can also be realized by CMP (Chemical Mechanical Polishing) and other processes, so that the performance of the second component 102 can be guaranteed and subsequent bonding between the first component 101 and the second component 102 can be facilitated.

S22, as shown in FIG. 10F, bonding the second substrate 102a to the first component 101, and after bonding, the recessed structure Vb is formed as a vacuum chamber.

After step S22, as shown in FIG. 10G, forming a first transmission member 102b, a second transmission member, and a third transmission member. At least a part of the first transmission member 102b is located in the first via V1 and connected to a first connection member of the plurality of connection members. At least a part of the second transmission member is located in the second via and is connected with a second connection member of the plurality of connection members. At least a part of the third transmission member is located in the third via and is connected to a third connection member of the plurality of connection members. And an insulating layer 102d, a first conductive member 102e, a second conductive member, and a third conductive member are formed on the second substrate 102a. The first conductive member 102e, the second conductive member and the third conductive member are all located on a side of the insulating layer 102d away from the second substrate 102a. The first conductive member 102e is connected to the first transmission member 102b through a via in the insulating layer 102d, the second conductive member is connected to the second transmission member through a via in the insulating layer 102d, and the third conductive member is connected to the third transmission member through a via in the insulating layer.

The positional relationship of the second transmission member, the third transmission member, the second connection member, the third connection member, the second conductive member and the third conductive member can be referred to above description of FIGS. 5B and 7. In addition, for the slave sensor, it is unnecessary to form the second transmission member, the third transmission member, the second conductive member and the third conductive member.

FIG. 9 is a block diagram of a detection apparatus provided in an embodiment of the present disclosure. As shown in FIG. 9, in some embodiments, the processing module 2 includes a signal amplification sub-module 201, an analog-to-digital conversion sub-module 202, and an analysis module 203. The signal amplification sub-module 201 is configured to amplify the output signals of the plurality of sensors 1 to obtain amplified signals of the plurality of sensors 1. The analog-to-digital conversion sub-module 202 is configured to perform analog-to-digital conversion on the output signals of the signal amplification sub-module 201 to obtain analog-to-digital conversion results of the plurality of sensors 1. The analysis module is configured to determine a detection result of the detection apparatus based on the analog-to-digital conversion results of the plurality of sensors 1.

In some embodiments, the analysis module 203 includes a monitor and an algorithm processor. The monitor is configured to determine a target signal range based on the analog-to-digital conversion results of the plurality of sensors 1, and determine whether there is an error result among the analog-to-digital conversion results of the plurality of sensors 1 according to the target signal range. The algorithm processor is configured to correct the error result in the presence of the error result, and perform analyzing and processing to determine the detection result of the detection apparatus according to the corrected result and the analog-to-digital conversion results of the remaining sensors 1.

When the analog-to-digital conversion result of a certain sensor 1 exceeds the target signal range, the analog-to-digital conversion result is an error result, and the corresponding sensor is labeled as an error sensor. At this time, the error result can be corrected according to the analog-to-digital conversion results of the remaining sensors 1. For example, the average value of analog-to-digital conversion results of the remaining sensors is taken as the corrected result. Alternatively, the analog-to-digital conversion results of the remaining sensors are filtered according to predetermined filtering parameters to obtain a corrected result. For example, when a certain sensor 1 is continuously marked as an error sensor for a period of time, the error sensor may be latched and isolated, and a fault message may be sent to remind the user.

It should be understood that when there is no error result, the analyzing and processing can be performed directly on the basis of the analog-to-digital conversion results of the plurality of sensors 1.

In some embodiments, the processing module 2 may further include a register (not shown) into which the monitor may send the error result for storage after determining the existence of the error result.

The processing module 2 may further include a power sub-module (not shown) for supplying power to the analysis sub-module 203, the mode conversion sub-module 202 and the signal amplification sub-module 201.

The present disclosure provides a training method of the detection apparatus according to any one of the above embodiments, the training method including the following steps:

S1, creating a model of the detection apparatus.

S2, obtaining a training set including a plurality of sample detection signals.

S3, inputting the sample detection signals into the model to obtain sample output signals. The excitation condition of the sensor 1 in the model and the predetermined interval duration of the processor in the model are adjusted according to the difference between the sample output signals and a target output signal, until a target training condition is satisfied.

In some embodiments, the excitation condition includes a first power supply voltage and a second power supply voltage provided to the sensor 1.

It should be understood that under certain other conditions, the longer the predetermined interval duration of the processor, the less the sensor is affected by the previous sampling time, that is, the lower the nonlinearity of the sensor. In addition, under certain other conditions, the sensing signals of the sensors will be different with the difference of the first power supply voltage and the second power supply voltage. Therefore, by adjusting a first power supply voltage, a second power supply voltage and the predetermined interval duration, the nonlinearity of a plurality of sensors can be optimized, so that the parameters of the neural network can be optimized, and the detection structure of the detection apparatus is more accurate.

It should be noted that the target training condition may be that a loss function determined according to the difference between the sample output signals and the target output signal is less than a preset value, or that the number of training times reaches a predetermined number.

It should also be noted that the model can be trained many times by using a plurality of sample detections in the training set, and the sample detection signals used in each training process are different.

FIG. 11 is a schematic diagram of a structure of a training apparatus of a detection apparatus provided in an embodiment of the present disclosure. As shown in FIG. 11, the present disclosure provides a training apparatus 500 of a detection apparatus, which includes a model creation module 100, a training set acquisition module 200 and a training module 300.

The model creation module 100 is configured to create a model of the detection apparatus.

The training set acquisition module 200 is configured to acquire a training set including a plurality of sample detection signals.

The training module 300 is configured to input the sample detection signals into the model to obtain sample output signals, and adjust the excitation condition of the sensor 1 in the model and the predetermined interval duration of the processor in the model according to the difference between the sample output signals and the target output signal, until a target training condition is satisfied.

The present disclosure provides a computer-readable storage medium having stored thereon a computer program, wherein when executed by a processor, the method in the above embodiments is implemented.

The computer-readable medium may include computer storage medium (or non-temporary medium) and communication medium (or temporary medium). As known to those of ordinary skills in the art, a term computer storage medium includes volatile and nonvolatile, removable and irremovable media implemented in any method or technology for storing information (for example, computer-readable instructions, a data structure, a program module, or other data). The computer storage medium includes, but is not limited to, a RAM, a ROM, an EEPROM, a flash memory or another memory technology, a CD-ROM, a Digital Versatile Disk (DVD) or another optical disk storage, a magnetic cartridge, a magnetic tape, magnetic disk storage or another magnetic storage apparatus, or any other medium that may be used for storing desired information and may be accessed by a computer. In addition, it is known to those of ordinary skills in the art that the communication medium usually includes computer-readable instructions, a data structure, a program module, or other data in a modulated data signal, such as, a carrier or other transmission mechanisms, and may include any information delivery medium.

It is to be understood that the above embodiments are only exemplary embodiments employed for the purpose of illustrating the principles of the present disclosure, however the present disclosure is not limited thereto. To those of ordinary skill in the art, various modifications and improvements may be made without departing from the spirit and substance of the present disclosure, and these modifications and improvements are also considered to be within the scope of the present disclosure.

1. A detection apparatus, comprising:
a plurality of micro electro mechanical system (MEMS) sensors configured to collect signals to be detected in real time and output sensing signals according to the signals to be detected;
a processor configured to receive the sensing signals of the plurality of MEMS sensors and determine a detection result of the detection apparatus according to the sensing signals of the plurality of MEMS sensors at each sampling time;
wherein there is a predetermined interval duration between two adjacent sampling times, and a sensing signal of each of the MEMS sensors at a current sampling time is related to a signal to be detected at the current sampling time, a sensing signal at a previous sampling time and an attenuation coefficient.

2. The detection apparatus according to claim 1, wherein the MEMS sensors comprise a MEMS pressure sensor.

3. The detection apparatus according to claim 1, wherein a MEMS sensor comprises a pressure sensing chamber and a pressure sensing layer located on a side of the pressure sensing chamber along a direction of a depth of the pressure sensing chamber, a maximum deformation of the pressure sensing layer is greater than ⅕ of a thickness of the pressure sensing layer; and a maximum stress of the pressure sensing layer is less than ⅕ of a yield strength of the pressure sensing layer.

4. The detection apparatus according to claim 3, wherein the MEMS sensor comprises:
a first component comprising the pressure sensing layer and a plurality of varistors disposed on the pressure sensing layer, the plurality of varistors being connected in series to form a Wheatstone bridge;
a second component bonded with the first component and defining the pressure sensing chamber;
wherein an orthographic projection of the varistors on the pressure sensing layer is within a range of an orthographic projection of the pressure sensing chamber on the pressure sensing layer; and the Wheatstone Bridge is electrically connected with the processor through the second component to transmit a sensing signal of the MEMS sensor to the processor.

5. The detection apparatus according to claim 4, wherein the first component further comprises a support portion, the pressure sensing layer is located on a side of the support portion facing the second component, and wherein the support portion and the pressure sensing layer are connected as an integral structure.

6. The detection apparatus according to claim 4, wherein the first component further comprises a plurality of connectors located on a side of the pressure sensing layer facing the second component; and the plurality of varistors are connected in series through the plurality of connectors.

7. The detection apparatus according to claim 6, wherein a connector comprises a connecting wire connecting two adjacent varistors and a bonding pad located on a side of the connecting wire close to the second component.

8. The detection apparatus according to claim 6, wherein the first component further comprises a first substrate, the varistors are disposed on the first substrate, the first substrate of the plurality of MEMS sensors is common, and the first substrate is further provided with a first power supply line and a second power supply line;
the plurality of connectors comprises a first connector, a second connector and a third connector; the second connector is electrically connected with the first power supply line, the third connector is electrically connected with the second power supply line, and the first connector is electrically connected with the processor through the second component.

9. The detection apparatus according to claim 8, wherein the second component comprises:
a second substrate bonded with the first component, a first via being provided on the second substrate;
a first conductive member located on a side of the second substrate facing away from the first component, the first conductive member being electrically connected with the first connector through a first transmission member, at least a part of the first transmission member being located in the first via;
wherein the first conductive member electrically connects the first connector with the processor.

10. The detection apparatus according to claim 9, wherein the plurality of MEMS sensors comprise a main sensor and a plurality of slave sensors, and a second via and a third via are further provided on the second substrate of the main sensor;
the second component of the main sensor further comprises:
a second conductive member located on a side of the second substrate facing away from the first component and electrically connected with the second connector through a second transmission member, at least a part of the second transmission member being located in the second via;
a third conductive member located on a side of the second substrate facing away from the first component and electrically connected with the third connector through a third transmission member, at least a part of the third transmission member being located in the third via;
wherein the second conductive member is electrically connected with a first power supply end, and the third conductive member is electrically connected with a second power supply end.

11. The detection apparatus according to claim 1, wherein a MEMS sensor comprises a second connector for receiving a first power supply signal and a third connector for receiving a second power supply signal;
the plurality of MEMS sensors includes a main sensor and a plurality of slave sensors, the main sensor and the plurality of slave sensors are arranged and connected in an array structure or a topology structure in which second connectors of any two connected MEMS sensors are connected and third connectors of any two connected MEMS sensors are connected.

12. The detection apparatus according to claim 11, wherein the topology structure comprises any one of a star topology structure, a ring topology structure, a tree topology structure, and a bus topology structure;
wherein in the star topology structure, the plurality of the slave sensors are located at a side of a first center line of the main sensor and are arranged in a row; in the ring topology structure, the plurality of the slave sensors are arranged around the main sensor; in the tree topology structure, the plurality of the slave sensors are located at a side of the first center line of the main sensor and arranged in a plurality of rows, and in two adjacent rows, the number of the slave sensors in a row close to the main sensor is less than the number of the slave sensors in a row far from the main sensor; in the bus topology structure, the plurality of the slave sensors are located at the same side of a second center line of the main sensor and distributed at opposite sides of the first center line of the main sensor;
wherein the first center line intersects with the second center line.

13. The detection apparatus according to claim 1, wherein the processor comprises:
a signal amplification sub-module configured to amplify output signals of the plurality of MEMS sensors to obtain amplified signals of the plurality of MEMS sensors;
an analog-to-digital conversion sub-module configured to perform analog-to-digital conversion on the output signals of the signal amplification sub-module to obtain analog-to-digital conversion results of the plurality of MEMS sensors;
an analysis module configured to determine a detection result of the detection apparatus based on the analog-to-digital conversion results of the plurality of MEMS sensors.

14. The detection apparatus according to claim 13, wherein the analysis module comprises:
a monitor configured to determine a target signal range based on the analog-to-digital conversion results of the plurality of MEMS sensors, and determine whether an error result exists in the analog-to-digital conversion results of the plurality of MEMS sensors according to the target signal range;
an algorithm processor configured to correct the error result in a case that the error result exists, and perform analyzing and processing to determine the detection result of the detection apparatus according to the corrected result and the analog-to-digital conversion results of other MEMS sensors.

15. A training method of the detection apparatus according to claim 1, comprising:
creating a model of the detection apparatus;
acquiring a training set comprising a plurality of sample detection signals;
inputting the sample detection signals into the model to obtain sample output signals;
adjusting an excitation condition of the MEMS sensors in the model and the predetermined interval duration of the processor in the model according to the difference between the sample output signals and a target output signal, until a target training condition is satisfied.

16. The training method according to claim 15, wherein the excitation condition comprises a first power supply voltage and a second power supply voltage provided to the MEMS sensors.

17. A training apparatus for a detection apparatus, comprising a processor and a memory storing processor-executable instructions that, when executed by the processor, cause the processor to perform the following operations:
creating a model of the detection apparatus;
acquiring a training set comprising a plurality of sample detection signals;
inputting the sample detection signals into the model to obtain sample output signals, and adjusting an excitation condition of micro electro mechanical system (MEMS) sensors in the model and a predetermined interval duration of a processor in the model according to the difference between the sample output signals and a target output signal, until a target training condition is satisfied.

18. A non-transitory computer-readable storage medium having stored thereon a computer program, wherein when the program is executed by a processor, the method according to according to claim 15 is implemented.
